(19) United States
(12) Patent Application Publication
(10) Pub. No.: US 2011/0309452 A1
(43) Pub. Date: Dec. 22, 2011

(54) METHODS OF MANUFACTURING SEMICONDUCTOR DEVICES

(75) Inventors: Yongkuk Jeong, Suwon-si (KR); Hyun-Kwan Yu, Suwon-si (KR); Ki-Eun Kim, Seoul (KR)

(73) Assignee: SAMSUNG ELECTRONICS CO., LTD., Suwon-si (KR)

(21) Appl. No.: 13/157,351

(22) Filed: Jun. 10, 2011

(30) Foreign Application Priority Data
Jun. 17, 2010 (KR) 10-2010-0057372

(51) Int. Cl. H01L 27/092; H01L 21/31

(52) U.S. Cl. 257/369; 438/703; 257/E27.062; 257/E21.24

(57) ABSTRACT

A semiconductor device includes a substrate, an NMOSFET and a PMOSFET disposed on the substrate, a first stress nitride layer pattern having a tensile stress and disposed On the NMOSFET, an interface oxynitride layer pattern having a first compressive stress and disposed on the PMOSFET and a second stress nitride layer pattern disposed on the interface oxynitride layer pattern and having a second compressive stress whose magnitude is greater than the magnitude of the first compressive stress.

### CROSS-REFERENCE TO RELATED APPLICATIONS AND CLAIM OF PRIORITY

This application claims priority under 35 U.S.C. §119 to Korean Patent Application No. 10-2010-0057372, filed on Jun. 17, 2010 in the Korean Intellectual Property Office, the contents of which are hereby incorporated herein by reference in its entirety.

### BACKGROUND

The inventive concept relates to semiconductor devices and methods of manufacturing the same. More particularly, the inventive concept relates to semiconductor devices including a stress nitride layer to improve electron mobility and methods of manufacturing the same.

Generally, in a process of forming a semiconductor device including a p-channel metal oxide semiconductor field effect transistor (PMOSFET) and an n-channel metal oxide semiconductor field effect transistor (NMOSFET), a semiconductor substrate may be bent and a compressive stress may be applied to an NMOSFET channel region and electron mobility may be lowered. In order to improve the bending problem of the semiconductor substrate, a silicon nitride layer having a tensile stress may be formed on the NMOSFET and a silicon nitride layer having a compressive stress may be formed on the PMOSFET of the semiconductor device to solve the compressive stress problem in the NMOSFET channel region.

According to the above-described method of using the silicon nitride layer as the stress nitride layer, the nitride layer formed on the PMOSFET may not solve the compressive stress problem at the substrate region including gate structures having wide gaps between them and may undergo lifting off the substrate. Accordingly, productivity of the semiconductor device may decrease.

### SUMMARY

Some embodiments provide semiconductor devices including a stress nitride layer for improving electron mobility.

Some embodiments provide methods of manufacturing semiconductor devices including a stress nitride layer suppressed from lifting.

According to some embodiments, a semiconductor device includes a substrate and an NMOSFET and a PMOSFET formed on the substrate. A first stress nitride layer pattern having a tensile stress is formed in the NMOSFET and an interface oxynitride layer pattern having a first compressive stress is formed in the PMOSFET. A second stress nitride layer pattern is formed on the interface oxynitride layer pattern. The second stress nitride layer pattern has a second compressive stress whose magnitude is greater than the magnitude of the first compressive stress.

In some embodiments, each of the NMOSFET and the PMOSFET may include a gate insulating layer pattern formed on the substrate, a gate electrode formed on the gate insulating layer pattern and source/drain regions formed at surface portions of the substrate adjacent to the gate electrode.

In some embodiments, each of the NMOSFET and the PMOSFET may further include a silicide layer formed on the gate electrode and the source/drain regions.

In some embodiments, the first compressive stress may be in a range of about −2.5 GPa to about −0.5 GPa.

In some embodiments, etch stopping layer patterns formed between the substrate and the first stress nitride layer pattern, and between the substrate and the interface oxynitride layer pattern, may be further included.

In some embodiments, the first stress nitride layer pattern and the second stress nitride layer pattern may include silicon nitride.

According to some embodiments, in methods of manufacturing a semiconductor device, an NMOSFET and a PMOSFET are formed on a substrate. A first stress nitride layer pattern having a tensile stress is formed on the NMOSFET and an interface nitride layer having a second compressive stress is formed on the first stress nitride layer pattern and in the PMOSFET. Then, a plasma oxidation is performed with respect to the interface nitride layer to form an interface oxynitride layer having a first compressive stress whose magnitude is less than the magnitude of the second compressive stress. A second stress nitride layer pattern having the second compressive stress is formed on the interface oxynitride layer of the PMOSFET. The interface oxynitride layer is partially removed to form an interface oxynitride layer pattern on the PMOSFET.

In some embodiments, the first stress nitride layer pattern, the interface nitride layer and the second stress nitride layer pattern may include silicon nitride.

In some embodiments, the first stress nitride layer pattern, the interface nitride layer and the second stress nitride layer pattern may be formed by a plasma enhanced chemical vapor deposition process.

In some embodiments, the plasma oxidation may be performed using at least one plasma gas selected from the group consisting of nitrous oxide (N₂O) gas, oxygen (O₂) gas and ozone (O₃) gas.

In some embodiments, the plasma oxidation may be performed so that the first compressive stress is in a range of from about −2.5 GPa to about −0.5 GPa.

In some embodiments, the plasma oxidation may be performed in-situ with the forming process of the interface nitride layer in a same chamber.

In some embodiments, the first stress nitride layer pattern may be formed as follows. A stress nitride layer may be formed on the substrate including the NMOSFET and the PMOSFET. A mask may be formed on the first stress nitride layer to expose the PMOSFET. The exposed portion of the first stress nitride layer may be removed using the mask.

In some embodiments, before forming the first stress nitride layer, a first etch stopping layer may be formed on the substrate including the NMOSFET and the PMOSFET.

In some embodiments, before forming the interface nitride layer, a second etch stopping layer may be formed on the mask and the substrate.

In some embodiments, a thickness of the interface nitride layer may be from about 10 Å to about 50 Å and a thickness of the second stress nitride layer is from about 300 Å to about 600 Å.

In some embodiments, the second stress nitride layer pattern may be formed as follows. A second stress nitride layer may be formed on the interface oxynitride layer. A hard mask may be formed on the second stress nitride layer to expose the PMOSFET. Then, the exposed portion of the second stress nitride layer may be removed using the hard mask.

In some embodiments, a first nitride layer having a compressive stress may be deposited on a PMOSFET formed on a substrate and a plasma oxidation may be performed. Then, a second stress nitride layer may be deposited. The magnitude of the compressive stress under the second stress nitride layer may be decreased to about −2.5 GPa or less. Thus, a lifting problem of the stress nitride layer generated on a silicide layer between gate structures of a PMOS region may be solved. In addition, an interface oxynitride layer releasing the compressive stress may be used as a buffer layer to improve a carrier mobility of the PMOSFET. A saturation drain current and current driving capacity of the PMOSFET may be increased. A semiconductor device having an improved driving capacity without generating a lifting of the stress nitride layer may be manufactured.

According to some embodiments, a device comprises: a substrate having an n-channel metal oxide semiconductor (NMOS) region and a p-channel metal oxide semiconductor (PMOS) region; at least one n-channel metal oxide semiconductor field effect transistor (NMOSFET) in the NMOS region, and a plurality of p-channel metal oxide semiconductor field effect transistors (PMOSFETs) in the PMOS region; a first stress nitride layer pattern having a tensile stress and disposed on the NMOSFET; and a stress nitride layer structure disposed in the PMOS region. At least in an area of the PMOS region between the PMOSFETs, the stress nitride layer structure includes: an interface oxynitride layer pattern having a first compressive stress on the substrate; and a second stress nitride layer pattern disposed on the interface oxynitride layer pattern and having a second compressive stress whose magnitude is greater than a magnitude of the first compressive stress.

In some embodiments, the first compressive stress is in a range of about −2.5 GPa to about −0.5 GPa.

In some embodiments, the second compressive stress is in a range of about −2.6 GPa to about −4.0 GPa

### BRIEF DESCRIPTION OF THE DRAWINGS

Example embodiments will be more clearly understood from the following detailed description taken in conjunction with the accompanying drawings. FIGS. 1 to 10 represent example embodiments as described herein.

FIG. 1 is a cross-sectional view for explaining a semiconductor device in accordance with some example embodiments.

FIGS. 2 to 10 are cross-sectional views for explaining a method of manufacturing a semiconductor device as illustrated in FIG. 1, in accordance with some example embodiments.

### DETAILED DESCRIPTION OF THE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of this specification and the relevant art and will not be interpreted in an idealized or overly formal sense unless expressly so defined herein.

Hereinafter, example embodiments on semiconductor devices and methods of manufacturing the same will be explained in detail.

FIG. 1 is a cross-sectional view for explaining a semiconductor device in accordance with some example embodiments.

Referring to FIG. 1, semiconductor device may include a substrate 100 formed by using a p-type single crystalline silicon wafer, an NMOSFET 272 and a PMOSFET 274 formed on substrate 100.

Substrate 100 may include a silicon substrate, a silicon germanium substrate, a silicon-on-insulator (SOI) substrate, etc.

On substrate 100, a device isolating layer 110 may be formed to separate the substrate 100 into an active region and a field region. NMOSFET 272 and PMOSFET 274 may be formed in the active region of substrate 100. The active region may be separated into an NMOS region (I) including NMOSFET 272 and a PMOS region (II) including PMOSFET 274. In the NMOS region (I), a p-type well doped with p-type impurities may be formed and in the PMOS region (II), an n-type well doped with n-type impurities may be formed.

NMOSFET 272 may include a first gate insulating layer pattern 212, a first gate electrode 222, a first source/drain region 242 functioning as a source/drain and a channel region (not labeled) under first gate insulating layer pattern 212. PMOSFET 274 may include a second gate insulating layer pattern 214, a second gate electrode 224, a second source/drain region 244 functioning as a source/drain and a channel region (not labeled) under second gate insulating layer pattern 214.

First and second gate electrodes 222 and 224 may include impurity doped polysilicon. In example embodiments, first gate electrode 222 may include n-type impurity doped polysilicon and second gate electrode 224 may include p-type impurity doped polysilicon.

First and second metal silicide layers 252 and 254 may be formed, respectively, on first gate electrode 222 and first source/drain region 242, and second gate electrode 224 and second source/drain region 244. Particularly, a cobalt silicide layer and a titanium silicide layer may be formed on first and second gate electrodes 222 and 224 and first and second source/drain regions 242 and 244.

A first gate structure 262 may include first gate insulating layer pattern 212, first gate electrode 222 and first metal silicide layer 252 formed on first gate electrode 222, and a second gate structure 264 may include second gate insulating layer pattern 214, second gate electrode 224 and second metal silicide layer 254 formed on second gate electrode 224.

On side surfaces of first and second gate electrodes 222 and 224, first and second spacers 232 and 234 formed by using silicon oxide or silicon nitride may be respectively formed.

MOSFETs 272 and 274 may have various structures, and the structures of MOSFETs 272 and 274 illustrated in the drawings may not limit the scope of the example embodiments.

On NMOSFET 272 and PMOSFET 274, first and second etch stopping layer patterns 312 and 354 may be formed, respectively. First and second etch stopping layer patterns 312 and 354 may be formed using silicon oxide. In some embodiments, first and second etch stopping layer patterns 312 and 354 may have a thickness of from about 10 Å to about 50 Å.

On first etch stopping layer pattern 312 of NMOSFET 272, a first stress nitride layer pattern 322 having a tensile stress may be formed.

First stress nitride layer pattern 322 may include silicon nitride. In some embodiments, the first stress nitride layer pattern 322 may have a thickness of from about 350 Å to about 600 Å.

The tensile stress of first stress nitride layer pattern 322 may have a stress value exceeding about 0 GPa. Particularly, the tensile stress may be from about +1 GPa to about +3 GPa.

On second etch stopping layer pattern 354 of PMOSFET 274, an interface oxynitride layer pattern 364 having a first compressive stress may be formed and a second stress nitride layer pattern 374 having a second compressive stress larger than the first compressive stress may be integrated on interface oxynitride layer pattern 364. Interface oxynitride layer pattern 364 may be formed as a buffer layer to prevent lifting at an interface of second stress nitride layer pattern 374 and second metal silicide layer 254.

Interface oxynitride layer pattern 364 may include silicon oxynitride and may be formed by means of a plasma enhanced chemical vapor deposition (PECVD) and a plasma oxidation process. In some embodiments, interface oxynitride layer pattern 364 may be formed by forming a silicon nitride layer on NMOSFET 272 and PMOSFET by means of PECVD, performing a plasma oxidation process with respect to the silicon nitride layer and partially removing the silicon nitride layer in order to be formed only on PMOSFET 274. While performing the PECVD process, hydrogen may be introduced into the silicon nitride layer and a compressive stress may be generated at the silicon nitride layer. However, while performing the plasma oxidation process, the compressive stress may be released to have a first compressive stress.

The first compressive stress of interface oxynitride layer pattern 364 may be about −2.5 GPa or more. Particularly, the first compressive stress may be in a range of from about −2.5 GPa to about −0.5 GPa. The thickness of interface oxynitride layer pattern 364 may be in a range of from about 10 Å to about 50 Å.

Second stress nitride layer pattern 374 may include the same material as first stress nitride layer pattern 322. In some embodiments, second stress nitride layer pattern 374 may include silicon nitride. Second stress nitride layer pattern 374 may be formed by means of PECVD process and may have a thickness range of from about 300 Å to about 600 Å.

The second compressive stress of second stress nitride layer pattern 374 may be about −2.5 GPa or less. In some embodiments, the second compressive stress may be in a range of from about −4.0 GPa to about −2.6 GPa.

Interface oxynitride layer pattern 364 and second stress nitride layer pattern 374 may increase carrier mobility of PMOSFET 274. In some embodiments, interface oxynitride layer pattern 364 may have a first compressive stress with a magnitude that is small enough to prevent lifting at an interface of metal silicide layer 254 formed between second gate structures 264 of PMOSFET 274. Second stress nitride layer pattern 374 may have a second compressive stress with a magnitude that is great enough to release tensile stress applied to a channel region of PMOSFET 274. Accordingly, lifting of second stress nitride layer pattern 374 from a wide plane including the gate structures having a wide gap therebetween may be prevented. Driving properties of PMOSFET 274 including hole mobility, saturated drain current, current driving capacity, etc., may be improved.

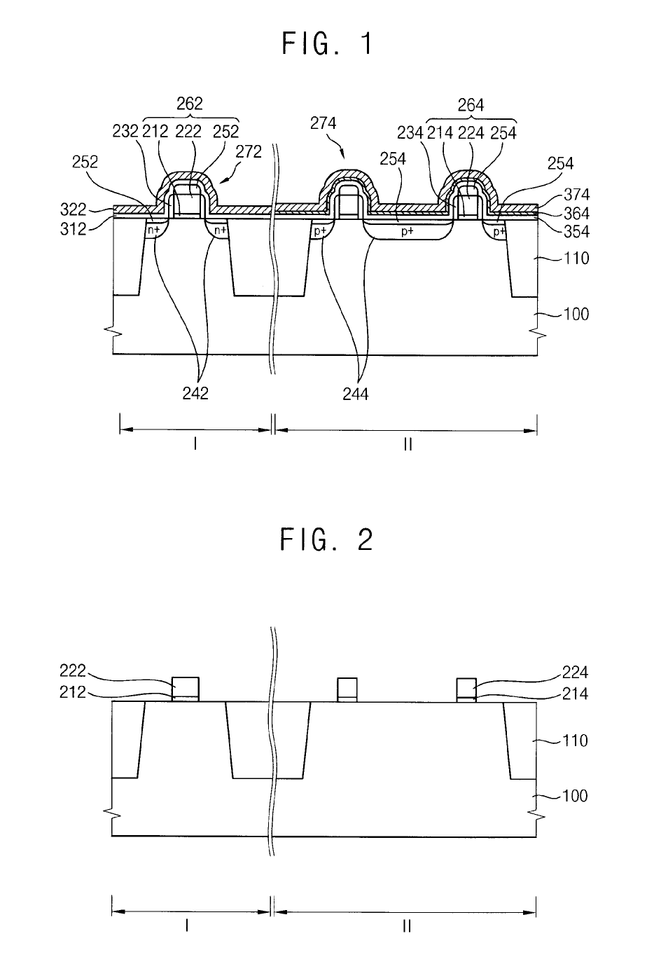

FIGS. 2 to 10 are cross-sectional views for explaining a method of manufacturing a semiconductor device in FIG. 1 in accordance with some example embodiments.

Referring to FIG. 2, a device isolation layer 110 may be formed on a p-type single crystalline silicon substrate 100 including a silicon wafer using a shallow trench isolation (STI) process to define an active region.

P-type impurities may be doped into an NMOS region (I) of substrate 100 to form a p-type well (not labeled) for forming an NMOSFET. N-type impurities may be doped into a PMOS region (II) of substrate 100 to form an n-type well (not shown) for forming a PMOSFET.

On the whole surface portion of substrate 100, a silicon oxide layer for forming first and second gate insulating layer patterns 212 and 214 may be formed by a thermal oxidation process. On the silicon oxide layer, a polysilicon layer for forming first and second gate electrodes 222 and 224 may be formed by means of a low pressure chemical vapor deposition (LPCVD) process.

The polysilicon layer may be selectively doped using the n-type impurities or the p-type impurities. Particularly, the p-type impurities may be doped into the polysilicon layer on the n-type well and the n-type impurities may be doped into the polysilicon layer on the p-type well.

The polysilicon layer and the silicon oxide layer may be successively patterned to form first gate electrode 222 and first gate insulating layer pattern 212 in the NMOS region (I), and to form second gate electrode 224 and second gate insulating layer pattern 214 in the PMOS region (II) of substrate 100.

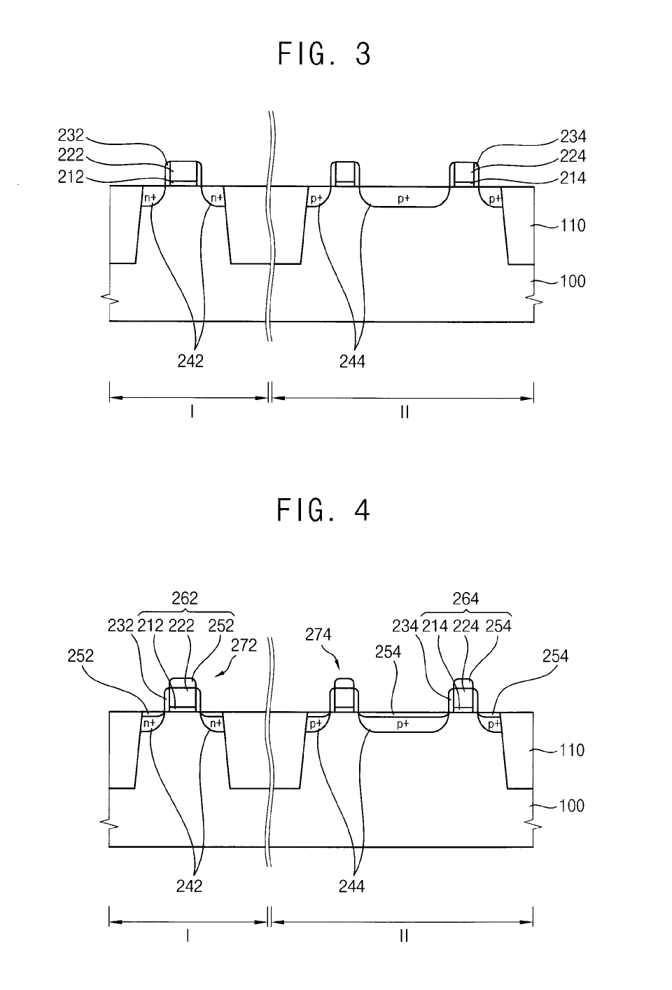

Referring to FIG. 3, first and second spacers 232 and 234 may be formed on side wall portions of first and second gate electrodes 222 and 224. First and second spacers 232 and 234 may be formed using silicon oxide or silicon nitride.

Particularly, a spacer layer (not shown) covering first and second gate electrodes 222 and 224 may be formed on substrate 100. The spacer layer may be anisotropically etched to form first and second spacers 232 and 234 on first and second gate electrodes 222 and 224.

A photoresist pattern (not shown) having an opening to expose the NMOS region (I) may be formed. N-type impurities may be doped using the photoresist pattern and first gate electrode 222 as ion doping masks to form first source/drain region 242 on the surface portion of the NMOS region (I) adjacent to first gate electrode 222. After forming first source/drain region 242, the photoresist pattern may be removed.

Similarly, a photoresist pattern (not shown) having an opening to expose the PMOS region (II) may be formed. P-type impurities may be doped using the photoresist pattern and second gate electrode 224 as ion doping masks to form a second source/drain region 244 on the surface portion of the PMOS region (II) adjacent to second gate electrode 224. After forming second source/drain region 244, the photoresist pattern may be removed.

On first and second gate electrodes 222 and 224, multiple spacers may be formed. The multiple spacers may include a screen oxide layer, a nitride layer spacer and an oxide layer spacer. The screen oxide layer may be formed by a re-oxidation process to cure damaged first and second gate insulating layer patterns 212 and 214 while performing a reactive ion etching for forming first and second gate electrodes 222 and 224. On the screen oxide layer, the spacer nitride layer and the spacer oxide layer may be successively integrated. The spacer oxide layer, the spacer nitride layer and the screen oxide layer may be anisotropically etched to form the multiple spacers. Particularly, a doping process of the n-type impurities and the p-type impurities may be further performed after forming the screen oxide layer.

As described above, constitution of first and second spacers 232 and 234 may vary. Accordingly, the constitution of the first and second spacers may not limit example embodiments.

Referring to FIG. 4, first and second metal silicide layers 252 and 254 may be formed, respectively, on top portions of first gate electrode 222 and a surface portion of first source/drain region 242, and on second gate electrode 224 and a surface portion of second source/drain region 244. Particularly, cobalt silicide layers or titanium silicide layers may be formed on first and second gate electrodes 222 and 224 and first and second source/drain regions 242 and 244.

In some embodiments, a cobalt layer or a titanium layer may be deposited on an entire surface portion of substrate 100 by means of a sputtering method. A thermal treatment may be performed to initiate a silicidation reaction between the cobalt layer or the titanium layer and first and second gate electrodes 222 and 224 and first and second source/drain regions 242 and 244.

As a result, in the NMOS region (I) of substrate 100, an NMOSFET 272 including first gate structure 262 including the successively integrated first gate insulating layer pattern 212, first gate electrode 222 and first metal silicide layer 252, first spacer 232 and first source/drain regions 242 may be obtained. Further, in the PMOS region (II), a PMOSFET 274 including a second gate structure 264 including the successively integrated second gate insulating layer pattern 214, second gate electrode 224 and second metal silicide layers 254, second spacer 234, and second source/drain regions 244 may be obtained.

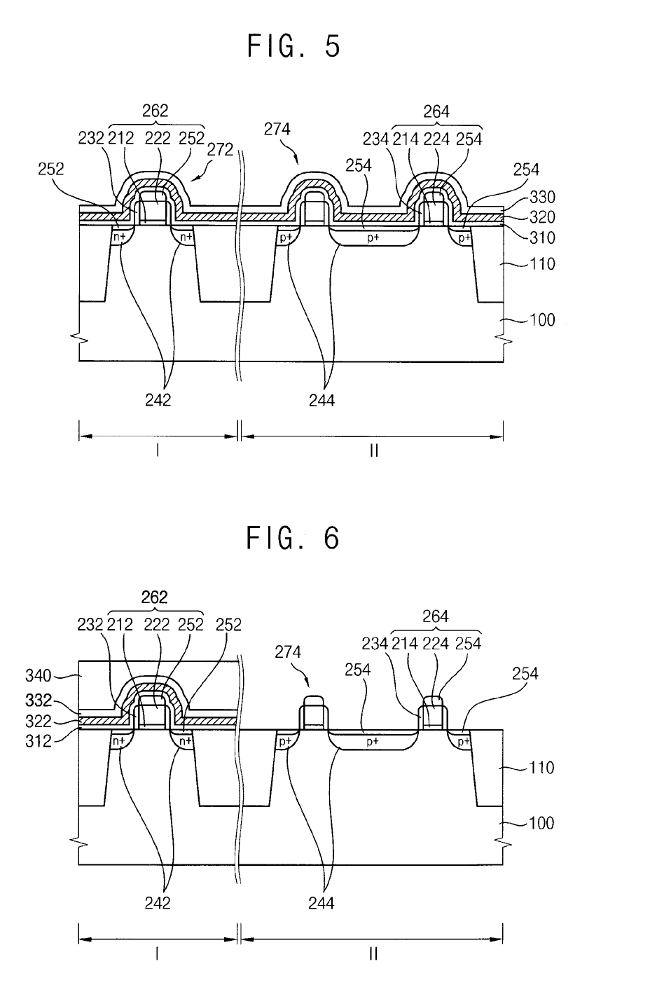

Referring to FIG. 5, a first etch stopping layer 310 including silicon oxide may be formed on the entire surface portion of substrate 100 including NMOSFET 272 and PMOSFET 274. First etch stopping layer 310 may prevent an etching of first and second gate structures 262 and 264 while performing an etching process with respect to a first stress nitride layer 320 to be formed on first etch stopping layer 310 in a subsequent process.

On first etch stopping layer 310, first stress nitride layer 320 having a tensile stress may be formed. First stress nitride layer 320 may be formed by depositing silicon nitride on first etch stopping layer 310 through a PECVD process. While performing the PECVD process, process conditions including, for example, a deposition pressure, gas inflowing velocity, a substrate temperature, and the degree of ion doping into the silicon nitride layer may be controlled to decrease bonding numbers of silicon-hydrogen and nitrogen-hydrogen to generate a positive stress value (i.e., tensile stress) of first stress nitride layer 320.

In accordance with some embodiments, the PECVD process may be performed under a pressure of from about 1 torr to about 10 torr at a substrate temperature of from about 300° C. to about 600° C., while applying a plasma power of from about 50 W to about 200 W. Particularly, the PECVD process may be performed using a silicon source material including silane (SiH₄), disilane, trisilane (TMS), etc., and a nitrogen source material including ammonia (NH₃) and nitrogen (N₂) plasma. An inflowing amount of silane may be from about 5 sccm to about 500 sccm, an inflowing amount of ammonia may be from about 10 sccm to about 10,000 sccm and an inflowing amount of nitrogen may be from about 1,000 sccm to about 30,000 sccm.

In some embodiments, first stress nitride layer 320 may be formed to a thickness of from about 300 Å to about 600 Å.

The tensile stress of first stress nitride layer 320 may have a stress value exceeding about 0 GPa. Particularly, the tensile stress may be from about +0.5 GPa to about +2 GPa.

On first stress nitride layer 320, a mask layer 330 including silicon nitride may be formed. Mask layer 330 may be formed as a mask for selectively etching first stress nitride layer 320 through an etching process to be performed in a following process.

Referring to FIG. 6, a photoresist layer (not shown) may be deposited on mask layer 330 and a photo process may be performed to form a photoresist pattern 340 having an opening to expose the PMOS region (II).

Mask layer 330 may be etched using photoresist pattern 340 to form a mask 332 exposing the PMOS region (II) on first stress nitride layer 320.

The exposed portion of first stress nitride layer 320 may be removed using mask 332 to form a first stress nitride layer pattern 322 only on first etch stopping layer 310 of NMOSFET 272. Through performing the process of forming first stress nitride layer pattern 322, first etch stopping layer 310 may also be changed into a first etch stopping layer pattern 312.

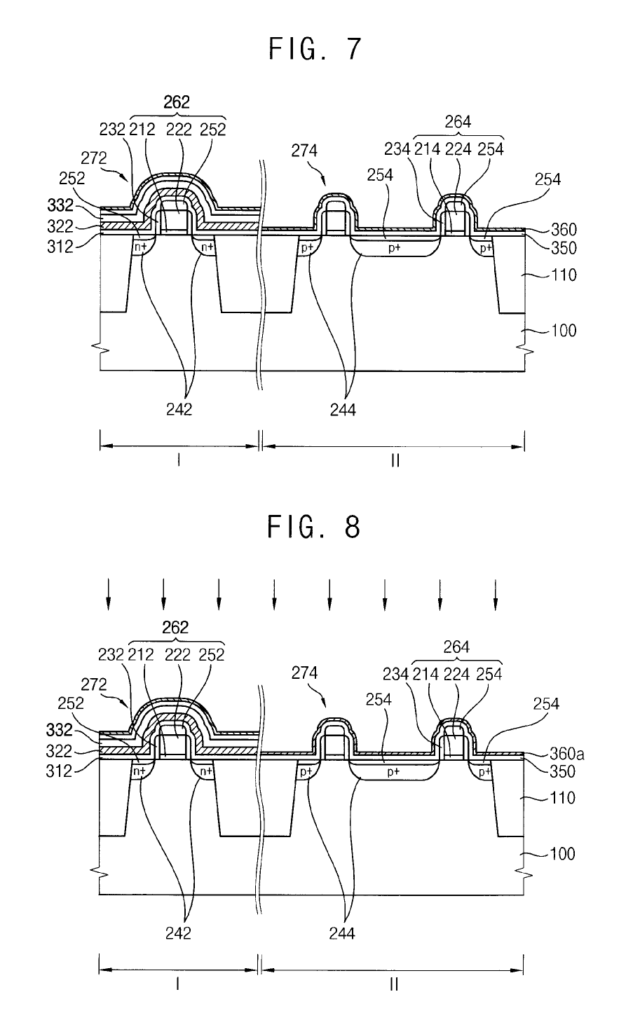

Referring to FIG. 7, photoresist pattern 340 may be removed after forming first stress nitride layer pattern 322. On first stress nitride layer pattern 322 and PMOSFET 274, a second etch stopping layer 350 may be formed using silicon oxide. Second etch stopping layer 350 may prevent first gate structure 262 from being etched while performing an etching process of interface nitride layer 360 to be formed on the second etch stopping layer in a subsequent process.

Interface nitride layer 360 having a second compressive stress may be formed on second etch stopping layer 350. Interface nitride layer 360 may be formed by depositing silicon nitride on second etch stopping layer 350 through a PECVD process. While performing the PECVD process, process conditions including, for example, a depositing pressure, gas inflowing velocity, a substrate temperature, and the degree of ion doping into the silicon nitride layer may be controlled to decrease bonding numbers of silicon-hydrogen and nitrogen-hydrogen to generate a negative stress value (i.e., compressive stress) of the interface nitride layer 360.

In accordance with some embodiments, the PECVD process may be performed under a pressure of from about 1 torr to about 4 torr at a substrate temperature of from about 300° C. to about 600° C., while applying a plasma power of from about 50 W to about 400 W. Particularly, the PECVD process may be performed using a silicon source material including silane (SiH₄), disilane, trisilane (TMS), etc., and a nitrogen source material including ammonia (NH₃) and nitrogen (N₂) plasma. Atmosphere gas may include argon (Ar) and hydrogen (H₂). An inflowing amount of silane may be from about 10 sccm to about 500 sccm, an inflowing amount of ammonia may be from about 50 sccm to about 10,000 sccm and an inflowing amount of nitrogen may be from about 500 sccm to about 20,000 sccm. An inflowing amount of argon may be from about 500 sccm to about 10,000 sccm and an inflowing amount of hydrogen may be from about 500 sccm to about 10,000 sccm.

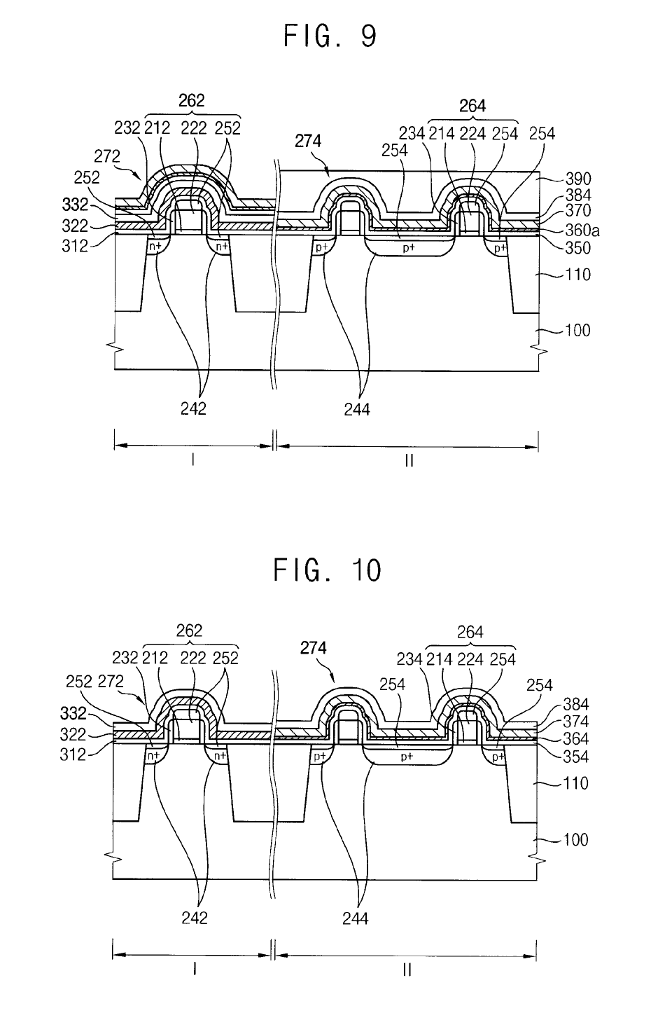

Interface nitride layer 360 may have the same second compressive stress as a second stress nitride layer 370 to be formed in a subsequent process (refer to FIG. 9). The second compressive stress of interface nitride layer 360 may have a negative stress value of about −2.5 GPa or less. Particularly, the second compressive stress may be in a range of from about −2.6 GPa to about −4.0 GPa. Interface nitride layer 360 may be formed to a thickness of from about 10 Å to about 50 Å.

Referring to FIG. 8, a plasma oxidation treatment exposing interface nitride layer 360 to a plasma may be performed to decrease the magnitude of the second compressive stress of interface nitride layer 360. After performing the plasma oxidation treatment, interface nitride layer 360 may be changed into an interface oxynitride layer 360a having a first compressive stress whose magnitude is less than the magnitude of the second compressive stress.

The plasma may include an oxygen atom and a gas that may cause an oxidation reaction with silicon nitride such as nitrous oxide (N₂O) gas, oxygen (O₂) gas, ozone (O₃) gas, etc. A mixture gas of the nitrous oxide (N₂O) gas, the oxygen (0₂) gas and the ozone (O₃) gas may be used.

In some embodiments, the plasma oxidation treatment may be performed in-situ in a chamber used for forming the interface nitride layer 360.

Through the plasma oxidation treatment, silicon bonding portions at a surface portion of interface nitride layer 360 may be changed into negative ions to react with oxygen atoms to generate silicon-oxygen (Si—O) bonding at the surface portion of the interface nitride layer 360. Thus formed interface oxynitride layer 360a may produce relatively loose bonding when comparing with silicon-nitrogen (Si—N) bonding to decrease inherent compressive stress. Particularly, the first compressive stress of interface oxynitride layer 360a may be in a range of from about −2.5 GPa to about −0.5 GPa.

When the first compressive stress is less than about −2.5 GPa, the second stress nitride layer 370 to be formed in a following process may generate a lifting problem. Accordingly, the first compressive stress of the interface oxynitride layer 360a may be in the range of from about −2.5 GPa to about −0.5 GPa. Then, lifting of second stress nitride layer 370 formed in a subsequent process at an interface with the second metal silicide layer 254 between second gate structures 264 of the PMOSFET 274 may be prevented.

Referring to FIG. 9, second stress nitride layer 370 having a second compressive stress may be formed on interface oxynitride layer 360a having the released first compressive stress.

Between second stress nitride layer 370 and second metal silicide layer 254, interface oxynitride layer 360a having the released first compressive stress may be formed. Therefore, a negative effect due to the high magnitude of the second compressive stress of second stress nitride layer 370 may be mitigated.

Second stress nitride layer 370 may be formed through the same process of forming interface nitride layer 360. Particularly, silicon nitride may be deposited on interface oxynitride layer 360a by a PECVD process. In this case, the depositing condition(s) of second stress nitride layer 370 may be the same as the depositing condition(s) of interface nitride layer 360. Therefore, second stress nitride layer 370 may have the same second compressive stress as that of interface nitride layer 360. In some embodiments, the second compressive stress of second stress nitride layer 370 may be in a range from about −4.0 GPa to about −2.6 GPa.

In some embodiments, second stress nitride layer 370 may be formed to a thickness of from about 300 Å to about 600 Å.

A hard mask layer (not shown) including silicon nitride may be formed on second stress nitride layer 370. A photoresist layer (not shown) may be formed on the hard mask layer and a photo process may be performed to form a photoresist pattern 390 having an opening to expose second stress nitride layer 370 in the NMOS region (I).

Referring to FIG. 10, a hard mask 384 may be formed by patterning the hard mask layer using photoresist pattern 390 exposing the NMOS region (I). Exposed portions of second stress nitride layer 370 and interface oxynitride layer 360a may be removed one by one using hard mask 384 to form an interface oxynitride layer pattern 364 and second stress nitride layer pattern 374 integrated on second etching mask layer 350 in the PMOS region (II). While forming interface oxynitride layer pattern 364, second etch stopping layer 350 may be changed into second etch stopping layer pattern 354. After forming interface oxynitride layer pattern 364, photoresist pattern 390 may be removed.

Mask 332 in the NMOS region (I) and hard mask 384 in the PMOS region (II) may be removed.

First stress nitride layer pattern 322 having a tensile stress may be completed in the NMOS region (I) including NMOSFET 272 as illustrated in FIG. 1. In the PMOS region (II) including PMOSFET 274, a double-layer structure of a stress nitride layer structure including interface oxynitride layer pattern 364 having the first compressive stress, and second stress nitride layer pattern 374 having the second compressive stress whose magnitude is greater than the magnitude of the first compressive stress, may be completed.

The double-layer structure of the stress nitride layer structure in the PMOS region (II) including interface oxynitride layer pattern 364 and second stress nitride layer pattern 374 formed on interface oxynitride layer pattern 364 may release the compressive stress at surface portions when compared with a structure including only the second stress nitride layer pattern. As a result, at a planar portion where there may be a wide gap between the second gate structures of the PMOSFETs, a lifting problem of second stress nitride layer pattern 374 may be prevented. Accordingly, a bending phenomenon of substrate 100 may be eliminated and stability of substrate 100 may be increased.

Further, since interface oxynitride layer pattern 364 having a released compressive stress may be used as a buffer layer instead of the commonly used silicon oxide layer, hole mobility at a channel region of PMOSFET 274 may be improved. Accordingly, saturation drain current and current driving capacity of PMOSFET 274 may also be increased.

In accordance with some embodiments, a first nitride layer having a compressive stress may be deposited on a PMOSFET formed on a substrate. A plasma oxidation treatment may be performed and the first nitride layer may be deposited further. The compressive stress under the stress nitride layer formed on the PMOSFET may decrease to about −2.5 GPa or less and lifting problem of the stress nitride layer generated on a silicide layer between gate structures in a PMOS region may be solved.

In addition, as an interface oxynitride layer releasing the compressive stress may be used as a buffer layer, carrier mobility of PMOSFET may be improved and a saturation drain current and current driving capacity of the PMOSFET may increase. A semiconductor device having improved driving capacity without generating the lifting problem of the stress nitride layer may be manufactured.

The foregoing is illustrative of example embodiments and is not to be construed as limiting thereof Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1-6. (canceled)

7. A method of manufacturing a semiconductor device, comprising:
forming an n-channel metal oxide semiconductor field effect transistor (NMOSFET) and a p-channel metal oxide semiconductor field effect transistor (PMOSFET) on a substrate;
forming a first stress nitride layer pattern having a tensile stress on the NMOSFET;
forming an interface nitride layer having a second compressive stress on the first stress nitride layer pattern and on the PMOSFET;
performing a plasma oxidation with respect to the interface nitride layer to form an interface oxynitride layer having a first compressive stress whose magnitude is less than a magnitude of the second compressive stress;
forming a second stress nitride layer pattern having the second compressive stress on the interface oxynitride layer of the PMOSFET; and
partially removing the interface oxynitride layer to form an interface oxynitride layer pattern on the PMOSFET.

8. The method of claim 7, wherein the first stress nitride layer pattern, the interface nitride layer and the second stress nitride layer pattern include silicon nitride.

9. The method of claim 7, wherein the first stress nitride layer pattern, the interface nitride layer and the second stress nitride layer pattern are formed by a plasma enhanced chemical vapor deposition process.

10. The method of claim 7, wherein the plasma oxidation is performed using at least one plasma gas selected from the group consisting of nitrous oxide (N₂O) gas, oxygen (O₂) gas and ozone (O₃) gas.

11. The method of claim 7, wherein the plasma oxidation is performed so that the first compressive stress is in a range of from about −2.5 GPa to about −0.5 GPa.

12. The method of claim 7, wherein the plasma oxidation is performed in-situ with the process of forming the interface nitride layer, in a same chamber.

13. The method of claim 7, wherein forming the first stress nitride layer pattern comprises:
forming a stress nitride layer on the substrate including the NMOSFET and the PMOSFET;
forming a mask on the first stress nitride layer to expose the PMOSFET; and
removing an exposed portion of the first stress nitride layer using the mask.

14. The method of claim 13, further performing prior to forming the stress nitride layer:
forming a first etch stopping layer on the substrate including the NMOSFET and the PMOSFET.

15. The method of claim 13, further performing prior to forming the interface nitride layer:
forming a second etch stopping layer on the mask and the substrate.

16. The method of claim 7, wherein a thickness of the interface nitride layer is from about 10 Å to about 50 Å and a thickness of the second stress nitride layer is from about 300 Å to about 600 Å.

17. The method of claim 13, wherein forming the second stress nitride layer pattern comprises:
forming a second stress nitride layer on the interface oxynitride layer;
forming a hard mask on the second stress nitride layer to expose the PMOSFET; and
removing an exposed portion of the second stress nitride layer using the hard mask.

18-20. (canceled)
